(19) United States
(12) Patent Application Publication
(10) Pub. No.: US 2026/0190789 A1
(43) Pub. Date: Jul. 2, 2026

(54) DISPLAY DEVICE

(71) Applicant: LG Display Co., Ltd., Seoul (KR)

(72) Inventors: Hyesun SONG, Seoul (KR); Hyesun SON, Seoul (KR); SangHoon OH, Seoul (KR)

(73) Assignee: LG Display Co., Ltd., Seoul (KR)

(21) Appl. No.: 19/436,353

(22) Filed: Dec. 30, 2025

(30) Foreign Application Priority Data
Dec. 31, 2024 (KR) 10-2024-0202621

(51) Int. Cl. H10K 59/80; H10K 102/00

(52) U.S. Cl. CPC H10K 59/873; H10K 2102/311

(57) ABSTRACT

A display device includes a display panel having a non-bending area, a first bending area corresponding to a side portion of the non-bending area, and a second bending area positioned between two first bending areas to correspond to a corner of the non-bending area. A back plate is disposed below the display panel to provide support, and an adhesive layer is interposed between the display panel and the back plate. The adhesive layer includes a first area corresponding to the non-bending area, a second area corresponding to the first bending area, and a third area corresponding to the second bending area. The first area and the third area have different physical properties to maintain adhesion and improve durability in the bending and corner regions, thereby enhancing the reliability of the display device.

### CROSS-REFERENCE TO RELATED APPLICATIONS

This application claims the priority of Korean Patent Application No. 10-2024-0202621 filed December 31, 2024 in the Korean Intellectual Property Office, the disclosure of which is incorporated herein by reference.

### BACKGROUND

### Technical Field

The present disclosure relates to a display device, and more particularly, to a display device in which an adhesive force in a bending area is maintained to be high and durability and reliability are improved.

### Description of the Related Art

In recent years, as society has entered a full-fledged information era, the field of display that processes and displays a large amount of information has rapidly developed. Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

Recently, flexible display devices manufactured to display images even when bent or folded like paper are attracting attention as next-generation display devices. The flexible display device may be classified into an unbreakable display device having high durability by utilizing a plastic thin film transistor substrate other than glass, a bendable display device which may be bent without breaking, a rollable display device which may be rolled, and a foldable display device which may be folded. Such a flexible display device has advantages in space utilization, interior, and design, and may have various application fields.

In particular, a cover glass is generally formed on the front surface of the display device, and the user may recognize the display screen through the cover glass. In this case, the cover glass generally has a flat shape, but in recent years, the demand for a curved display device in which an edge portion of the cover glass has a curved shape has increased. In the curved display device, a screen may be recognized through a cover glass even on some side surfaces of the display device, thereby obtaining an effect of expanding a substantial screen size.

In the curved display device, a display panel which has a flat shape at a center portion and maintains a bent shape at a side portion including an edge is disposed so as to correspond to a cover glass shape. At this time, stress is generated on the adhesive layer disposed between the display panel bent at the side portion and the substrate supporting the same, and durability problems such as peeling of the display panel and the support substrate, occurrence of creases, wrinkles and bubbles on the corner, or peeling off have occurred.

### BRIEF SUMMARY

The present disclosure relates to a flexible or curved display device designed to improve durability and adhesion in its corner and bending regions. It introduces a multi-zone adhesive layer positioned between the display panel and the back plate, where each area has distinct physical properties. The non-bending region employs a pressure sensitive adhesive that facilitates lamination during manufacturing, while the corner region employs a curable adhesive with a higher modulus and greater adhesive strength to resist peeling and deformation caused by stress. This configuration ensures strong adhesion in high-stress areas while maintaining efficient production.

The back plate is configured to complement the adhesive structure by accommodating bending stress. Its thickness is reduced in areas that undergo bending, particularly at the corners, and may include tapered regions, surface textures, or openings that distribute stress, improve flexibility, and enhance bonding with the adhesive. By adjusting the structure in this manner, the restoring force that leads to peeling is reduced, and the formation of wrinkles or bubbles in curved regions is prevented.

Additional features include the use of black dye or pigments that change color upon exposure to heat or ultraviolet energy within the adhesive, thereby preventing light reflection and concealing underlying structural patterns. Together, these structural and material arrangements achieve a display device with improved reliability, mechanical stability, and optical quality suitable for curved and foldable applications.

Various embodiments of the present disclosure provide a display device including a corner having a curved surface portion.

Various embodiments of the present disclosure provide a display device which effectively relieves stress applied to a corner of the display device to minimize peeling between an adhesive layer and an adherend.

Various embodiments of the present disclosure provide a display device capable of solving creases, wrinkles and air bubbles generated at a corner of the display device.

Technical benefits of the present disclosure are not limited to the above-mentioned benefits, and other benefits, which are not mentioned above, can be clearly understood by those skilled in the art from the following descriptions.

A display device according to an exemplary embodiment of the present disclosure includes a display panel including a non-bending area, a first bending area corresponding to a side portion of the non-bending area, and a second bending area positioned between two first bending areas to correspond to a corner of the non-bending area; a back plate supporting the display panel at a lower portion of the display panel; and an adhesive layer disposed between the display panel and the back plate and including a first area corresponding to the non-bending area, a second area corresponding to the first bending area, and a third area corresponding to the second bending area, the first area and the third area having different physical properties from each other.

Other detailed matters of the embodiments are included in the detailed description and the drawings.

According to the present disclosure, in the display device, materials or physical properties of the adhesive layer disposed in the non-bending area and the bending area are configured to be different to improve the durability and reliability of the display device while ensuring mass production of the display device.

According to the present disclosure, in the display device, peeling, wrinkles, and bubbles generated between the display panel and the back plate at a corner having a curved surface portion can be suppressed.

According to the present disclosure, in the display device, the bending stress and the restoring force to be restored to a shape before being bent are reduced through the structural characteristics of the back plate, and the adhesive force with the adhesive layer may be improved.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic perspective view of a display device according to an exemplary embodiment of the present disclosure.

FIG. 2 is a schematic cross-sectional view of a display device according to an exemplary embodiment of the present disclosure.

FIG. 3 is a schematic plan view for explaining an adhesive layer of a display device according to an exemplary embodiment of the present disclosure.

FIG. 4 is a schematic plan view for explaining an adhesive layer of a display device according to another exemplary embodiment of the present disclosure.

FIG. 5 is a schematic cross-sectional view of a display device according to still another exemplary embodiment of the present disclosure.

FIG. 6 is a schematic plan view for explaining a back plate of a display device according to another embodiment.

FIGS. 7A to 7F are schematic diagrams for explaining various shapes of a back plate of a display device according to still another exemplary embodiment of the present disclosure.

FIG. 8 is a schematic cross-sectional view of a display device according to still another exemplary embodiment of the present disclosure.

FIG. 9 is a schematic cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

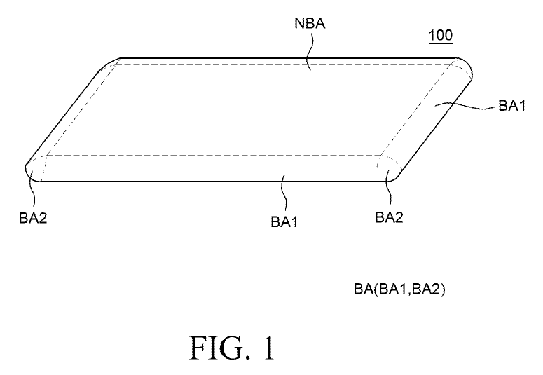

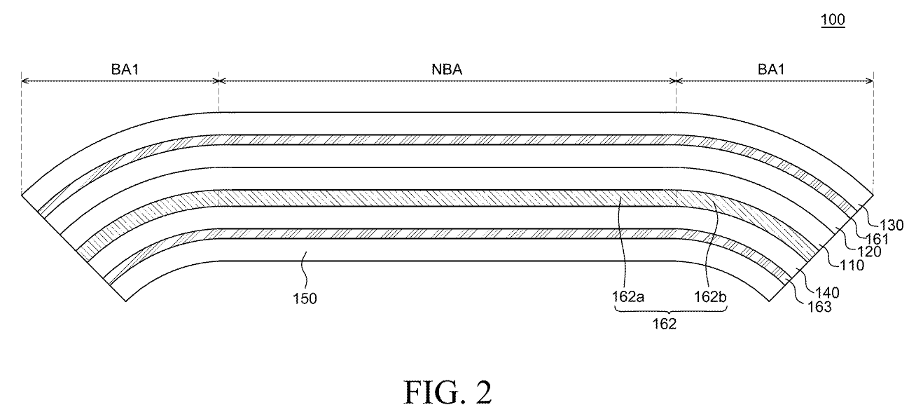

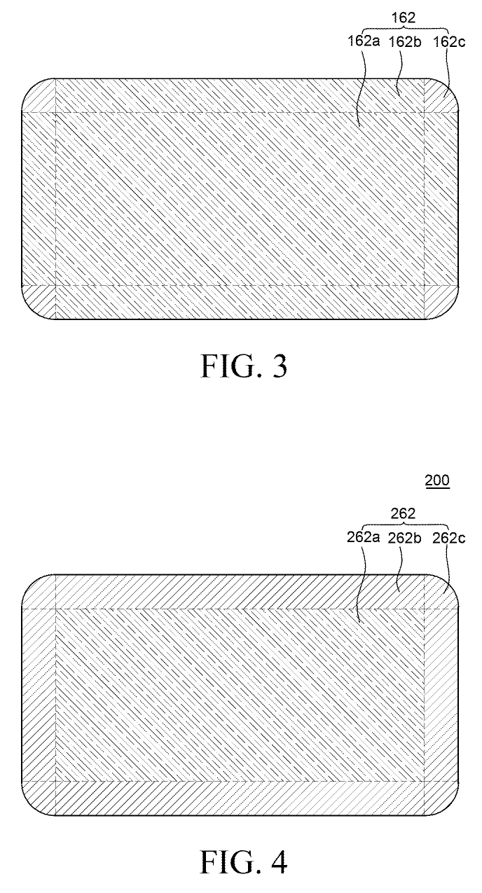

FIG. 1 is a schematic perspective view of a display device according to an exemplary embodiment of the present disclosure. FIG. 2 is a schematic cross-sectional view of a display device according to an exemplary embodiment of the present disclosure. FIG. 3 is a schematic plan view for explaining an adhesive layer of a display device according to an exemplary embodiment of the present disclosure.

Referring to FIGS. 1 and 2, a display device 100 according to an exemplary embodiment of the present disclosure includes a display panel 110, a polarization film 120, a cover glass 130, a back plate 140, and a metal plate 150.

The display panel 110 is a panel in which an image is implemented, and a display element for implementing an image and a circuit unit for driving the display element may be disposed. For example, when the display device 100 is an organic light emitting display device, the display element may include an organic light emitting element. Hereinafter, for convenience of description, it is assumed that the display device 100 according to the exemplary embodiment of the present disclosure is a display device including an organic light emitting element, but it is not limited thereto.

The circuit unit may include various thin film transistors, capacitors, wirings, and driving ICs for driving the organic light emitting element. For example, the circuit unit may include various configurations such as a driving thin film transistor, a switching thin film transistor, a storage capacitor, a gate line, a data line, a gate driver IC, and a data driver IC, but is not limited thereto.

The display panel 110 is a flexible panel in which a driving thin film transistor and a light emitting element are formed on a flexible substrate is encapsulated by an encapsulation unit, and includes the flexible substrate having a very thin thickness to implement flexibility and a display element disposed on the flexible substrate.

The flexible substrate may be formed of an insulating material having flexibility, and for example, may be an insulating plastic substrate selected from polyimide, polyethersulfone, polyethylene terephthalate, and polycarbonate.

Referring to FIGS. 1 and 2, the display panel 110 includes a non-bending area NBA and a bending area BA.

The non-bending area NBA is an area in which the display panel 110 is maintained in a flat state. The non-bending area NBA may be entirely composed of a display area or may be composed of a display area and a non-display area surrounding the display area, but is not limited thereto.

The bending area BA is an area where the display panel 110 is bent. The bending area BA may be an area extending from a side portion and a corner of the non-bending area NBA. In this case, the bending area BA may be entirely or partially configured as a display area, or a part of the bending area BA may be configured as a non-display area, but is not limited thereto.

The bending area BA includes a first bending area BA1 corresponding to a side portion of the non-bending area NBA and a second bending area BA2 corresponding to a corner of the non-bending area NBA.

First, the first bending area BA1 is disposed to correspond to the side portion of the non-bending area NBA. That is, the first bending area BA1 is an area extending from the side portion of the non-bending area NBA. As illustrated in FIG. 1, when the non-bending area NBA has a rectangular shape, the first bending area BA1 may be an area which extends from four sides of the non-bending area NBA and is bent with a specific radius of curvature. For example, the first bending area BA1 may be bent with a complex curvature of about 5 mm to 8 mm.

The second bending area BA2 is disposed so as to correspond to a corner of the non-bending area NBA. That is, the second bending area BA2 is an area extending from the corner of the non-bending area NBA. As illustrated in FIG. 1, when the non-bending area NBA has a rectangular shape, the second bending area BA2 may be an area which extends from four corners of the non-bending area NBA and is bent with a specific radius of curvature. For example, the second bending area BA2 may be bent with a complex curvature of about 5 mm to 8 mm.

The first bending area BA1 and the second bending area BA2 are disposed to surround the non-bending area NBA and may be alternately disposed. That is, the second bending area BA2 may be disposed between the two first bending areas BA1, and the first bending area BA1 may be disposed between the two second bending areas BA2.

Meanwhile, the display device 100 according to the exemplary embodiment of the present disclosure may include a display area and a non-display area. The display area is an area in which a plurality of pixels are disposed to substantially display an image. The non-display area may be positioned to surround the display area. The non-display area is an area in which an image is not substantially displayed, and various wiring lines, driving ICs, printed circuit boards, and the like for driving pixels and driving circuits disposed in the display area are disposed. For example, in the non-display area, various ICs such as a gate driver IC and a data driver IC, VSS lines, and the like may be disposed. As described above, the display area may be disposed only in the non-bending area NBA or extended from the non-bending area NBA to be disposed in at least a part of the bending area BA.

When the direction in the drawing is defined with reference to FIG. 2, under the premise that the display surface of the display device 100 faces forward, the polarization film 120 and the cover glass 130 are positioned on the display panel 110 in the direction of the display surface of the display device 100, and the back plate 140 and the metal plate 150 are positioned below the display panel 110 in the direction of the rear surface of the display device 100. Each of the components is attached through adhesive layers 161, 162, and 163.

The polarization film 120 is disposed on the display panel 110. The polarization film 120 polarizes the light emitted from the display panel 110 to a polarization angle. The polarization film 120 emits light polarized at a polarization angle to the outside. The polarization film 120 may include a function of blocking reflection of light excluding light polarized at a polarization angle among external light. In the meantime, even though in FIG. 2, it is illustrated that the display device 100 includes a polarization film 120, the polarization film 120 may be omitted depending on the design.

In order to protect the display panel 110 from external impact and prevent damage such as scratches, the cover glass 130 is disposed above the display panel 110.

Referring to FIGS. 1 and 2, the cover glass 130 may have a curved surface having a preset radius of curvature corresponding to the bending area BA. For example, the cover glass 130 may be bent such that an edge portion corresponding to the bending area BA has a curved surface. Specifically, the cover glass 130 includes a front surface portion which is a plane corresponding to the non-bending area NBA, a first curved surface portion which is located on a side portion of the front surface portion and corresponds to the first bending area BA1, and a second curved surface portion which is located on a corner and corresponds to the second bending area BA2. The first curved surface portion extends from the front surface portion and is bent with a specific radius of curvature. As illustrated in FIG. 1, when the non-bending area NBA has a rectangular shape, the front surface portion also has a rectangular shape, and the first curved surface portion extends from four side portions of the curved surface portion to be bent. The four first curved surface portions positioned on the four side portions of the curved surface portion may have the same radius of curvature or may have some different radius of curvature. The second curved surface portion is located at the corner of the cover glass 130 to connect the two first curved surface portions. The second curved surface portion may be a curved surface having at least two curvatures. Accordingly, the cover glass 130 has a four-sided bending structure in which the edges and corners are entirely bent to improve the aesthetics of the electronic device and reduce the bezel width in each of the long-side direction and the short-side direction of the display device.

Meanwhile, although not shown in FIG. 2, a touch panel constituting a touch sensor may be selectively disposed between the display panel 110 and the cover glass 130, if necessary.

A back plate 140 for supporting the display panel 110 may be included on the rear surface of the display panel 110. The back plate 140 supports the display panel 110 at a lower portion of the display panel 110. Since the back plate 140 is disposed above two plates (i.e., the back plate 140 and the metal plate 150) disposed on the rear surface of the display panel 110, the back plate 140 may be referred to as a top plate. The back plate 140 may be, for example, a metal material such as stainless steel (SUS) or Invar, or may be formed of plastic such as polymethylmetacrylate (PMMA), polycarbonate (PC), polyvinylalcohol (acrylonitrile-styrene (PVA), ABS), acrylonitrile-butadiene-styrene polyethylene terephthalate (PET), silicone, or polyurethane (PU), but is not limited thereto.

When the display device 100 is bent, the back plate 140 maintains a constant curvature of the display panel 110 and suppresses creases generated on the upper surface of the display panel 110. Further, the back plate 140 is disposed between the display panel 110 and the metal plate 150 to suppress a phenomenon in which a plurality of openings formed in the metal plate 150 is transferred onto the display screen or the display screen is distorted by the plurality of openings.

A metal plate 150 for supporting the display panel 110 is disposed on the rear surface of the back plate 140. At this time, the metal plate 150 supports the flexible substrate constituting the display panel 110 so as not to sag and protects components disposed on the flexible substrate from external moisture, heat, impact, and the like.

Since the metal plate 150 is disposed below two plates (i.e., the back plate 140 and the metal plate 150) disposed on the rear surface of the display panel 110, it may be referred to as a bottom plate. The metal plate 150 may be made of a material such as stainless steel (SUS) and amorphous metal which are rigid to maintain the shape of the display panel 110, but is not limited thereto.

Meanwhile, the metal plate 150 may include an opening pattern or an uneven pattern disposed in the bending area BA. Since the metal plate 150 is made of a metal material and has rigidity, a pattern may be formed in the bending area BA to allow the metal plate 150 to be easily bent.

The adhesive layers 161, 162, and 163 are components for adhering elements constituting the display device 100 to each other. Referring to FIG. 2, a display device 100 according to an exemplary embodiment of the present disclosure includes a first adhesive layer 161 disposed between the polarization film 120 and the cover glass 130, a second adhesive layer 162 disposed between the display panel 110 and the back plate 140, and a third adhesive layer 163 disposed between the back plate 140 and the metal plate 150. In the meantime, even though in FIG. 2, it is illustrated that the adhesive layers 161, 162, and 163 include a first adhesive layer 161, a second adhesive layer 162, and a third adhesive layer 163, the first adhesive layer 161 and the third adhesive layer 163 may be omitted depending on whether components are used or a placement structure.

The first adhesive layer 161 is disposed between the polarization film 120 and the cover glass 130 to attach the polarization film 120 and the cover glass 130. In the meantime, even though in FIG. 2, it is illustrated that the polarization film 120 is disposed on the display panel 110, when the polarization film 120 is excluded or disposed in a different position, the first adhesive layer 161 may be disposed to attach between the display panel 110 and the cover glass 130.

The first adhesive layer 161 may be formed of an optical clear adhesive (OCA) or an optical clear resin (OCR) having a high light transmittance so that light emitted from the display panel 110 is well transmitted to the front surface while providing an adhesive force capable of maintaining the folding characteristic in the bending area BA. For example, the first adhesive layer 161 may be an acrylic resin, and as long as it is an acrylic resin used as an adhesive member in the art, it is not particularly limited and may be appropriately selected and used.

The third adhesive layer 163 is disposed between the back plate 140 and the metal plate 150 to attach the back plate 140 and the metal plate 150. The third adhesive layer 163 may be formed of a pressure sensitive adhesive (PSA) capable of providing adhesion and elasticity capable of maintaining folding characteristics in the bending area BA. Meanwhile, the third adhesive layer 163 may be omitted when the metal plate 150 is not disposed.

The second adhesive layer 162 may be disposed between the display panel 110 and the back plate 140 to attach the display panel 110 and the back plate 140. In this case, the second adhesive layer 162 is configured such that at least a part of an area corresponding to the non-bending area NBA and an area corresponding to the bending area BA have different physical properties. Further, at least a part of an area corresponding to the non-bending area NBA and an area corresponding to the bending area BA in the second adhesive layer 162 may be made of different materials. Hereinafter, the second adhesive layer 162 will be described in detail with reference to FIG. 3 together.

FIG. 3 is a schematic plan view for explaining an adhesive layer of a display device according to an exemplary embodiment of the present disclosure.

Referring to FIGS. 2 and 3, the second adhesive layer 162 includes a first area 162a corresponding to the non-bending area NBA, a second area 162b corresponding to the first bending area BA1, and a third area 162c corresponding to the second bending area BA2. The first area 162a forms a flat surface corresponding to the non-bending area NBA. The second area 162b extends from the first area 162a and has a bent shape. For example, the second area 162b extends from four side portions of the first area 162a so as to overlap the first bending area BA1. The third area 162c connects the two second areas 162b. The third area 162c is located at a corner of the second adhesive layer 162 to overlap the second bending area BA2.

The third area 162c of the second adhesive layer 162 may be formed of a material different from that of the first area 162a and the second area 162b. Specifically, the first area 162a corresponding to the non-bending area NBA and the second area 162b corresponding to the first bending area BA1 may be formed of a pressure sensitive adhesive PSA. The pressure-sensitive adhesive can impart high adhesion. Accordingly, the first area 162a of the second adhesive layer 162 corresponding to the non-bending area NBA may secure an adhesive force between the display panel 110 and the back plate 140. In addition, since the pressure-sensitive adhesive can impart adhesion and elasticity to maintain bending characteristics, the bent shape can be maintained while securing adhesion between the display panel 110 and the back plate 140 in the first bending area BA1 having a constant radius of curvature. In addition, since the pressure-sensitive adhesive is configured in the form of a tape, the adhesive process may be easily performed through a lamination process, thereby securing process ease during the manufacturing process of the display device.

Meanwhile, the third area 162c corresponding to the second bending area BA2 may be formed of a curable adhesive. The third area 162c overlaps the second bending area BA2, which is the corner area of the display device 100. The second bending area BA2 is an area disposed between the first bending areas BA1 having a constant radius of curvature and may have a curved surface that may be bent with a complex curvature. In the second bending area BA2, the adhesive strength between the components may be easily lowered due to the large bending stress. In particular, in the second bending area BA2, since the display panel 110 and the back plate 140 have a greater bending stress and a greater restoring force to return to their original shape before bending than the cover glass 130, a problem may occur in that the gap between the display panel 110 and the back plate 140 in the second bending area BA2 is peeled off or the adhesive force is reduced. Accordingly, in the second adhesive layer 162 between the display panel 110 and the back plate 140, a curable adhesive having a high adhesive force and a modulus that changes according to the curing condition is used in the third area 162c corresponding to the second bending area BA2, thereby securing the adhesive force in the second bending area BA2 and preventing peeling of the back plate 140 and the display panel 110.

The curable adhesive may be made of a photocurable material or a thermosetting material. For example, the photocurable material may be formed using an ultraviolet (ultra Violet) curable resin, but is not limited thereto. The thermosetting material may be one compound selected from the group consisting of an epoxy-based, urethane-based, ester-based, and polyimide-based resin, or a mixture or copolymer of two or more, but is not limited thereto.

Since the third area 162c of the second adhesive layer 162 is formed of a material different from that of the first area 162a and the second area 162b, the third area 162c may have different physical properties. Specifically, the third area 162c of the second adhesive layer 162 may have a greater adhesive force than the first area 162a and the second area 162b. As described above, the second bending area BA2 disposed between the two first bending areas BA1 has a complex curvature (e.g., two or more curvatures) to correspond to a corner of the display device 100 so that a great stress is applied to the display panel 110 and the back plate 140 in the second bending area BA2. Therefore, the third area 162c of the second adhesive layer 162 corresponding to the second bending area BA2 is configured to have a greater adhesive force than the first area 162a and the second area 162b, which may improve the durability between the display panel 110 and the back plate 140.

Further, the third area 162c of the second adhesive layer 162 may have a Young’s modulus which is greater than that of the first area 162a and the second area 162b. When the third area 162c corresponding to the second bending area BA2 has a larger Young’s modulus than the first area 162a and the second area 162b, the performance of the adhesive layer may be maintained even at a high temperature due to the high crosslinking density, thereby improving the durability and adhesion of the display device.

Specifically, the Young’s modulus values of the first area 162a and the second area 162b may be 1×10⁶ Pa or less, and the Young’s modulus value of the third area 162c may be 1×10⁷ Pa or more, but are not limited thereto. When the Young’s modulus value of each area of the second adhesive layer 162 satisfies the above range, the adhesive strength at the corner of the display device may be improved while maintaining the overall process convenience of the second adhesive layer 162, thereby solving the problem of peeling, creases, wrinkles, or air bubbles caused by the restoring force which is to be restored to the shape before the component is bent.

Accordingly, in the display device 100 according to the exemplary embodiment of the present disclosure, among the components constituting the second adhesive layer 162 disposed between the display panel 110 and the back plate 140, the third area 162c corresponding to the second bending area BA2, which is the corner of the display device 100, is configured with a different material so as to have a relatively large adhesive force and modulus compared to the remaining areas, thereby improving the adhesive force between the display panel 110 and the back plate 140 at the corner of the display device 100 and improving the reliability.

Further, the first area 162a corresponding to the non-bending area NBA is formed of a tape-type pressure sensitive adhesive so that the second adhesive layer 162 may be easily adhered through physical force by a simple process such as a lamination process, and the additional curing process may be omitted by forming a curable adhesive only in the third area 162c which is an edge portion requiring a partially strong adhesive force. That is, when the entire area of the second adhesive layer 162 is formed of a curable adhesive, the curing process must be performed on the front surface of the display device, so that the processability is deteriorated, and other components may be affected during the curing process, or the rework process may not be easy due to too strong adhesion. In the display device according to the exemplary embodiment of the present disclosure, by using different types of adhesives, it is possible to secure partial adhesion and improve both the processability of the adhesive layer and the stability of the display device.

FIG. 4 is a schematic plan view for explaining an adhesive layer of a display device according to another exemplary embodiment of the present disclosure. A display device 200 illustrated in FIG. 4 is substantially identical in configuration to the display device 100 illustrated in FIGS. 1 to 3, except for a second adhesive layer 262. Therefore, repeated descriptions of the identical components will be omitted.

First, referring to FIG. 4, the second adhesive layer 262 includes a first area 262a corresponding to the non-bending area NBA, a second area 262b corresponding to the first bending area BA1, and a third area 262c corresponding to the second bending area BA2. In this case, the second area 262b and the third area 262c of the second adhesive layer 262 may be formed of a material different from the first area 262a or may have different physical properties.

Specifically, the second area 262b and the third area 262c of the second adhesive layer 262 may be formed of a curable adhesive, and the first area 262a may be formed of a pressure-sensitive adhesive. In this case, the second area 262b and the third area 262c of the second adhesive layer 262 may have a greater adhesive force than the first area 262a. In addition, the second area 262b and the third area 262c of the second adhesive layer 262 may have a Young’s modulus greater than that of the first area 262a.

Unlike the case where only the third area 162c of the second adhesive layer 162 illustrated in FIG. 3 is formed of a curable adhesive and the first area 162a and the second area 162b are formed of a pressure sensitive adhesive, the second area 262b of the second adhesive layer 262 illustrated in FIG. 4 may also be formed of the same material as or have the same physical properties as the third area 262c corresponding to the second bending area BA2.

Like the embodiment as illustrated in FIG. 3, in the display device 200 illustrated in FIG. 4, the third area 262c of the second adhesive layer 262 improves an adhesive force between the display panel 110 and the back plate 140 in the second bending area BA2 which is a corner area of the display device 200. Through this, it is possible to solve the phenomenon that creases, wrinkles and bubbles are formed due to peeling between the display panel 110 and the back plate 140 or a decrease in adhesion in the second bending area BA2. Furthermore, in the display device 200 illustrated in FIG. 4, the second area 262b of the second adhesive layer 262 corresponding to the first bending area BA1 is also formed of a curable adhesive as in the third area 262c so that the second area 262b may have the same adhesive strength and modulus as the third area 262c. Accordingly, the adhesive strength between the display panel 110 and the back plate 140 may be improved even in the first bending area BA1, and the reliability of the display device may be improved. In the meantime, even though in FIG. 4, it is illustrated that all the second areas 262b corresponding to the four first bending areas BA1 positioned on the side with respect to the first area 262a corresponding to the non-bending area NBA are configured by a curable adhesive as in the third area 262c, it is not limited thereto and only a part of the second areas 262b corresponding to the four first bending areas BA1 is made of the same material as the third area 262c and has the same physical properties. For example, only the second area 262b corresponding to two first bending areas BA1 which face each other among the four first bending areas BA1 may be formed of a curable adhesive such as the third area 262c, and the second area 262b corresponding to the other two first bending areas BA1 may be formed of a pressure sensitive adhesive such as the first area 262a.

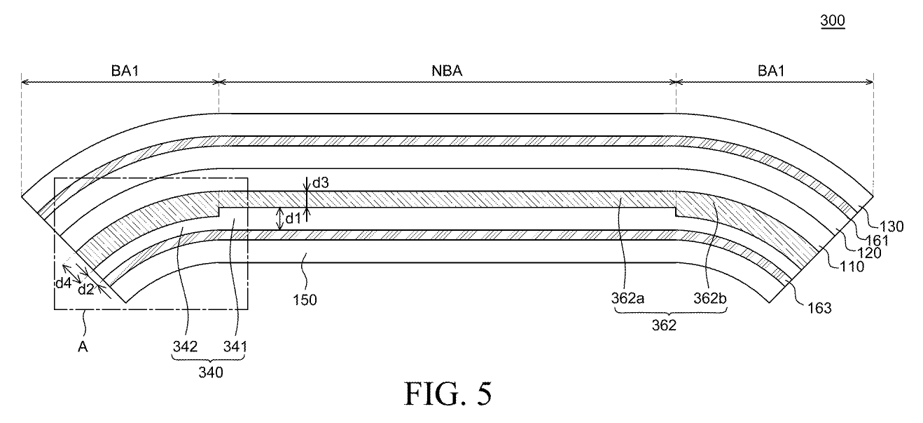

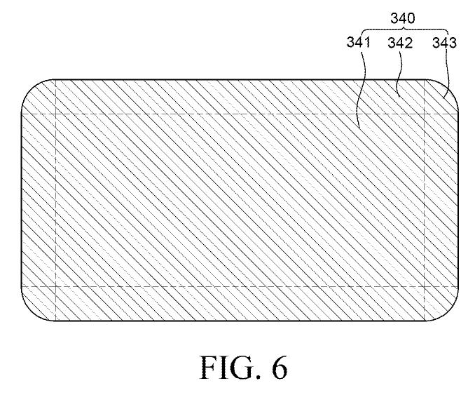

FIG. 5 is a schematic cross-sectional view of a display device according to still another exemplary embodiment of the present disclosure. FIG. 6 is a schematic plan view for explaining a back plate of a display device according to another embodiment. A display device 300 illustrated in FIG. 5 has the substantially same configuration as the display device 100 illustrated in FIG. 4 except for the back plate 340 and the second adhesive layer 362, so that a redundant description will be omitted.

Referring to FIGS. 5 and 6, the back plate 340 includes a first back plate 341 corresponding to the non-bending area NBA, a second back plate 342 corresponding to the first bending area BA1, and a third back plate 343 corresponding to the second bending area BA2.

The first back plate 341 may be disposed at a position corresponding to the non-bending area NBA of the display device 300. Therefore, the first back plate 341 may be disposed below the display panel 110 including the non-bending area NBA having a rectangular shape in a shape corresponding to the non-bending area NBA. The first back plate 341 may be disposed on a central portion of the back plate 340 and may have a flat upper surface.

The second back plate 342 may be disposed at a position corresponding to the first bending area BA1. That is, the second back plate 342 may extend from the side portion of the first back plate 341. As illustrated in FIG. 6, when the first back plate 341 has a rectangular shape, the second back plate 342 may extend from four sides of the first back plate 341. Accordingly, the second back plate 342 may be disposed to surround the sides of the first back plate 341.

The third back plate 343 may be disposed in an area corresponding to the second bending area BA2. The third back plate 343 is located at the corner of the back plate 340 and connects the two second back plates 342. The third back plate 343 may have a curvature shape having complex curvature (e.g., two or more curvatures).

The first back plate 341, the second back plate 342, and the third back plate 343 may be integrally formed. For example, the first back plate 341, the second back plate 342, and the third back plate 343 may be formed of the same material and formed as one body. However, the present disclosure is not limited thereto, and the first back plate 341, the second back plate 342, and the third back plate 343 may be separately formed and then connected to each other.

Referring to FIG. 5, the back plate 340 used in the display device 300 according to still another exemplary embodiment of the present disclosure may have different thickness in the non-bending area NBA and in the bending area. Specifically, the thickness d2 of the second back plate 342 located in the first bending area BA1 is smaller than the thickness d1 of the first back plate 341 located in the non-bending area NBA, and a step is formed between the first back plate 341 and the second back plate 342. Although not illustrated in FIG. 5, similarly, the thickness of the third back plate 343 located in the second bending area BA2 is smaller than the thickness d1 of the first back plate 341 located in the non-bending area NBA, and a step is formed between the first back plate 341 and the third back plate 343. In this case, the thickness of the third back plate 343 may be less than or equal to the thickness d2 of the second back plate 342. Specifically, the thickness d1 of the first back plate 341 may be 50 μm to 250 μm or 100 μm to 150 μm, and the thickness d2 of the second back plate 342 may be 10 μm to 200 μm or 10 μm to 50 μm. Since the thicknesses of the second back plate 342 and the third back plate 343 corresponding to the bending area BA are smaller than that of the first back plate 341 corresponding to the non-bending area NBA, the bending stress and the restoring force to return to their original shape before bending may be reduced.

On the other hand, by implementing the thickness of the back plate 340 partially differently, the thickness of the second adhesive layer 362 disposed on the back plate 340 is also implemented differently for each area. Specifically, the thickness d3 of the first area 362a of the second adhesive layer 362 corresponding to the non-bending area NBA is smaller than the thickness d4 of the second area 362b of the second adhesive layer 362 corresponding to the first bending area BA1. That is, because the second area 362b of the second adhesive layer 362 corresponds to the second back plate 342 having a thickness smaller than that of the first back plate 341, the second area 362b of the second adhesive layer 362 may have a thickness larger than that of the first area 362a corresponding to the first back plate 341. Likewise, a thickness of the third area (not shown) of the second adhesive layer 362 corresponding to the second bending area BA2 may be larger than the thickness of the first area 362a and may be the same as the thickness of the second area 362b.

Specifically, a thickness d3 of the first area 362a of the second adhesive layer 362 may be 10 μm to 100 μm, and a thickness d4 of the second area 362b of the second adhesive layer 362 may be greater than 10 μm and less than or equal to 250 μm.

The second area 362b and the third area 362c of the second adhesive layer 362 corresponding to the bending area NA have a greater thickness than the first area 362a corresponding to the non-bending area NBA. As the thicknesses of the second back plate 342 and the third back plate 343 corresponding to the bending area BA are implemented to be smaller than the first thickness of the non-bending area NBA, the thicknesses of the second area 362b and the third area of the second adhesive layer 362 may be increased. Accordingly, since the adhesive force between the display panel 110 and the back plate 340 in the bending area BA may be greatly improved, it is possible to solve the phenomenon that creases, wrinkles and bubbles are formed due to the peeling or the decrease in the adhesive force between the display panel 110 and the back plate 340.

Meanwhile, FIGS. 5 and 6 illustrate that the second back plate 342 and the third back plate 343 have a smaller thickness than the first back plate 341. However, the second back plate 342 and the first back plate 341 may have the same thickness, and only the third back plate 343 corresponding to the second bending area BA2 may have a smaller thickness than the second back plate 342 and the first back plate 341. Accordingly, the thickness of the third area of the second adhesive layer 362 corresponding to the second bending area BA2 may be greater than the thicknesses of the first area 362a and the second area 362b. Specifically, as illustrated in FIGS. 1 to 3, when the third area 162c of the second adhesive layer 162 corresponding to the second bending area BA2 is formed of a material different from or different from the physical properties of the first area 162a and the second area 162b, in order to improve the adhesive strength of the second adhesive layer 362 in the second bending area BA2 and reduce the restoring force of the back plate 340, the thickness of the third back plate 343 corresponding only to the second bending area BA2 may be reduced and the thickness of the third area of the second adhesive layer 362 may be improved.

Meanwhile, the second area 362b and/or the third area 362c of the second adhesive layer 362 may further include a black dye or a black pigment. By including a black dye or a black pigment in the second area 362b and/or the third area 362c of the second adhesive layer 362 positioned in the bending area BA, reflection from the external light unit may be prevented outside the display device 300.

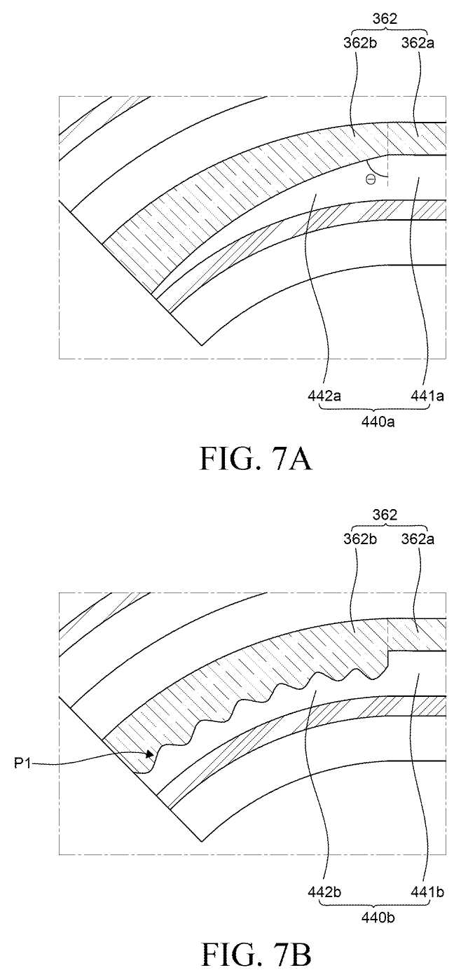

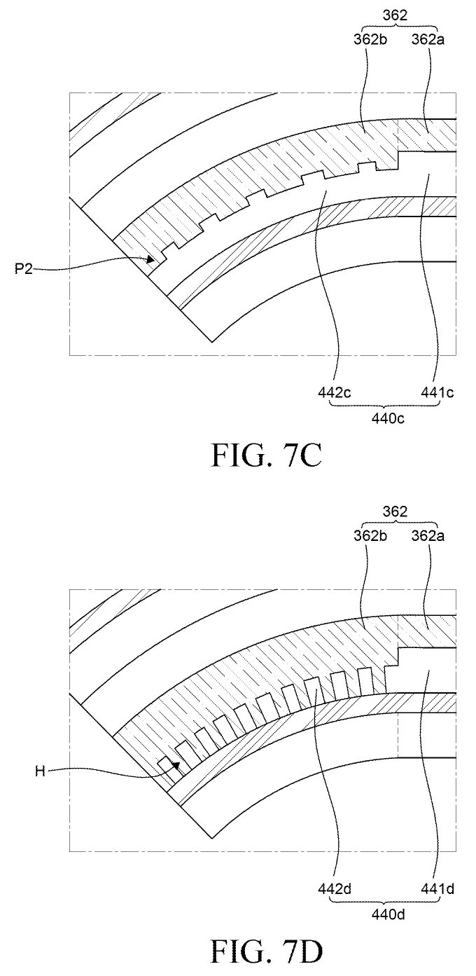

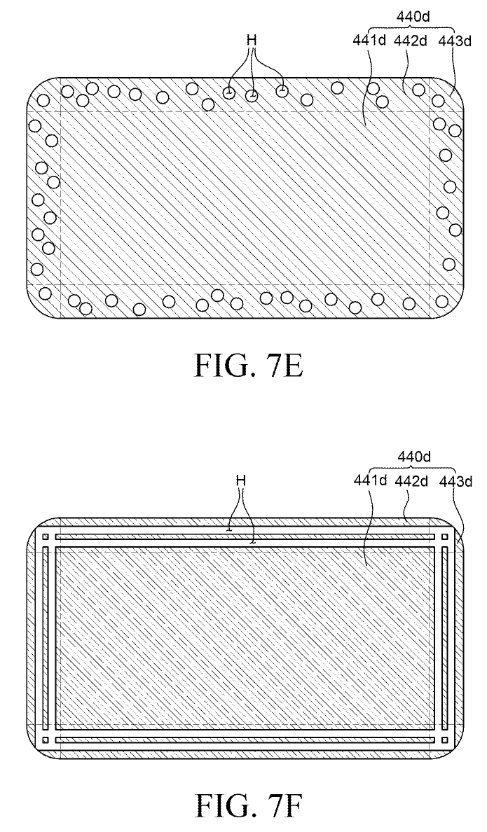

FIGS. 7A to 7F are schematic diagrams for explaining various shapes of a back plate of a display device according to still another exemplary embodiment of the present disclosure.

FIG. 7A is a schematic enlarged cross-sectional view for explaining a first embodiment of a back plate of a display device according to still another exemplary embodiment of the present disclosure. FIG. 7A is an enlarged cross-sectional view of an area A of FIG. 5.

Referring to FIG. 7A, the thickness of the second back plate 442a corresponding to the first bending area BA gradually decreases from a portion adjacent to the first back plate 441a toward the outside. That is, the thickness of the second back plate 442a may decrease toward the outside of the display device 300. At this time, the surface of the second back plate 442a may form an angle θ of 1o to 45o with respect to the vertical line of the surface of the first back plate 441a. Similarly, although not shown in FIG. 7A, the thickness of the third back plate of the back plate 440a corresponding to the second bending area BA2 decreases with increasing distance from the first back plate 441a.

In this case, the thickness of the second area 362b of the second adhesive layer 362 corresponding to the first bending area BA1 is gradually increased from a portion adjacent to the first area 362a corresponding to the non-bending area NBA toward the outside of the first bending area BA1. Similarly, although not shown in FIG. 7A, the thickness of the third area of the second adhesive layer 362 corresponding to the second bending area BA2 increases with increasing distance from the first area 362a.

The second back plate 442a disposed in the first bending area BA1 has the thickest thickness in a portion adjacent to the first back plate 441a disposed in the non-bending area NBA and has a thickness that gradually decreases to have the thinnest thickness at the outermost side of the first bending area BA1. Therefore, in the first bending area BA1 adjacent to the non-bending area NBA, sufficient rigidity and support for the display panel 110 may be ensured, while reducing bending stress in the first bending area BA1 and a restoring force to return to their original shape before bending.

FIG. 7B is a schematic enlarged cross-sectional view for explaining a second embodiment of a back plate of a display device according to still another exemplary embodiment of the present disclosure. FIG. 7B is an enlarged cross-sectional view of an area A of FIG. 5.

Referring to FIG. 7B, a plurality of patterns P1 may be disposed on a upper surface of the second back plate 442b. For example, a plurality of concave patterns P1 may be formed on the upper surface of the second back plate 442b. Meanwhile, the plurality of patterns P1 is not limited thereto and may have a shape recessed from the upper surface of the second back plate 442b toward the lower surface thereof. Here, the "upper surface" may refer to the surface on a side towards the display surface of the display device 300, and the "lower surface" may refer to the surface on a side towards the rear surface of the display device 300Although not illustrated in FIG. 7B, a plurality of concave patterns may also be formed on the upper surface of the third back plate, and the upper surface of the second back plate 442b may be flat and a plurality of concave patterns may be formed only on the upper surface of the third back plate.

When the plurality of concave patterns P1 is formed on the upper surface of the second back plate 442b, the pressure on the second back plate 442b may be reduced. Specifically, in the case of the display device 300 that bends to the corner of the display panel 110, a compressive stress may be applied to the bending area BA. Accordingly, when the flat back plate 440b is bent to have a curved shape in the bending area BA, shrinkage deformation may occur depending on the bending direction.

Therefore, the plurality of concave patterns is formed on the upper surface of the second back plate 442b or the third back plate of the back plate 440b corresponding to the bending area BA to reduce a stress applied to the back plate 440b positioned in the bending area BA and may be easily bent.

In particular, the amount of contraction and deformation in the area corresponding to the corner of the display device 2 may be greater than the amount of contraction and deformation in the side area of the display device 2. Accordingly, compressive stress may be generated in various directions in the corner area of the display panel 110, and greater compressive stress may be applied compared to other bending areas BA. In this case, the shrinkage of the corner areas of the display panel 110 does not proceed smoothly, which may cause wrinkles or damage to the corner areas of the display panel 110. Accordingly, a plurality of patterns may be formed only on the third back plate corresponding to the second bending area BA2.

FIG. 7C is a schematic enlarged cross-sectional view for explaining a third embodiment of a back plate of a display device according to still another exemplary embodiment of the present disclosure. FIG. 7C is an enlarged cross-sectional view of area A of FIG. 5.

Referring to FIG. 7C, a plurality of uneven patterns P2 may be formed on the upper surface of the second back plate 442c. Although not illustrated in FIG. 7C, a plurality of uneven patterns may also be formed on the upper surface of the third back plate, and the upper surface of the second back plate 442c may be flat and a plurality of uneven patterns may be formed only on the upper surface of the third back plate.

When the plurality of uneven patterns P2 is formed on the upper surface of the second back plate 442c, the pressure on the second back plate 442c may be reduced. In addition, the adhesive force with the second adhesive layer 362 may be improved by the uneven pattern P2. Therefore, by forming the plurality of uneven patterns P2 on the upper surface of the back plate 440c corresponding to the bending area BA, the stress applied to the back plate 440c located in the bending area BA may be reduced and easily bent, and the adhesive force with the second adhesive layer 362 is improved to suppress the peeling phenomenon between the display panel 110 and the back plate 440c in the bending area BA.

FIG. 7D is a schematic enlarged cross-sectional view for explaining a first embodiment of a back plate of a display device according to still another exemplary embodiment of the present disclosure. FIG. 7D is an enlarged cross-sectional view of an area A of FIG. 5. FIGS. 7E and 7F are schematic plan views for explaining the back plate 440d illustrated in FIG. 5.

Referring to FIG. 7D, a plurality of holes H, that is, an opening pattern is formed in the second back plate 442d. At this time, in FIGS. 7E and 7F, a plurality of holes H are formed not only in the second back plate 442d but also in the third back plate 443d. However, the present disclosure is not limited thereto. A hole may not be formed in the second back plate 442d, and a plurality of holes H may be formed only in the third back plate 443d.

The plurality of holes H formed in the second back plate 442d and the third back plate 443d corresponding to the bending area BA disperses the stress concentrated when the back plate 440d is bent in the bending area BA, so that the back plate 440d may be easily bent. Further, the second adhesive layer 362 extends in the plurality of holes H to improve a bonding force between the second adhesive layer 362 and the back plate 440d. Accordingly, peeling or bubble generation of the back plate 440d may be suppressed.

Referring to FIG. 7E, the plurality of holes H is illustrated as having a circular shape in plan view, but is not limited thereto. For example, the plurality of holes H may have an oval shape or a square shape. Meanwhile, the density of the holes H included in the third back plate 443d corresponding to the second bending area BA2 may be larger than the density of the holes H included in the second back plate 442d corresponding to the first bending area BA1. The second bending area BA2 in which the two first bending areas BA1 are in contact is subjected to a greater stress than in the first bending area BA1, such that the back plate 440d may be easily peeled off from the second adhesive layer 362. Therefore, in order to reduce the stress of the third back plate 443d and further increase the adhesive force with the second adhesive layer 362, the third back plate 443d may have a larger number of holes than the second back plate 442d based on the same area.

Further, referring to FIG. 7F, the plurality of holes H may have a long rectangular shape. Specifically, each hole H may have a shape extending in the longitudinal direction along the side portion of the back plate 440d. FIG. 7F illustrates that the plurality of holes H are formed on all four surfaces along the length direction of the side portion, but is not limited thereto. For example, the plurality of holes H may be formed on some of the four sides along the length direction of the side portion.

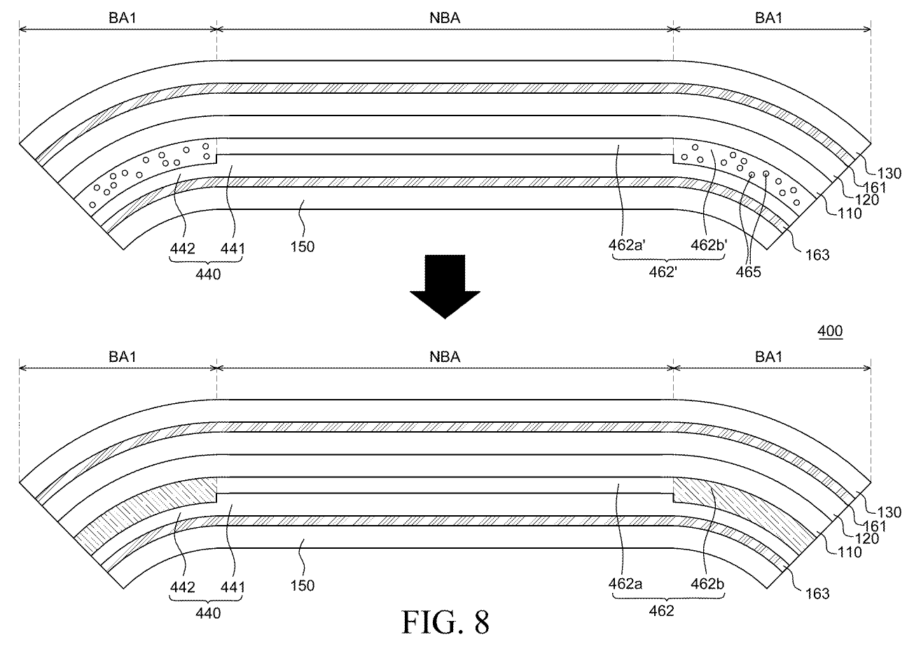

FIG. 8 is a schematic cross-sectional view of a display device according to still another exemplary embodiment of the present disclosure.

In FIG. 8, a schematic cross-section of the display device before and after the curing process of the second adhesive layer 462 is described. Referring to FIG. 8, an adhesive 462′ for forming a second adhesive layer is disposed between the display panel 110 and the back plate 440. At this time, a pressure sensitive adhesive 462a′ is disposed in an area corresponding to the non-bending area NBA and a curable adhesive 462b′ is disposed in an area corresponding to the first bending area BA. At this time, the curable adhesive 462b′ may further include a black dye or a black pigment. As illustrated in FIGS. 7B to 7D, when a plurality of patterns are formed on the second back plate 442 corresponding to the first bending area BA, the second area 462b of the second adhesive layer 462 may suppress the pattern of the second back plate 442 positioned at the bottom from being visually recognized by turning on the black color.

Meanwhile, the black dye or the black pigment may be a discolored particle (also referred to as ‘a color-changing particle’) due to heat or energy irradiation. Specifically, referring to FIG. 8, the black dye or the black pigment may be encapsulated pigment particles 465 having a structure in which discolored particles including solvent are surrounded by a capsule film. The encapsulated pigment particles 465 are discolored to black as the capsule is decomposed during the curing process of the curable adhesive 462b′. Accordingly, after curing, the second area 462b of the second adhesive layer 462 may have a black color and the first area 462a may maintain a transparent color. Accordingly, the color of the required area may be changed by using the curing process of the second adhesive layer. Meanwhile, the black dye or the black pigment may be a color-changing resin material whose color changes according to heat or energy irradiation.

Although the case where the second area 462b of the second adhesive layer 462 corresponding to the first bending area BA1 is formed by the curable adhesive has been illustrated in FIG. 8, referring to FIGS. 3 and 4, only the third area (not shown in FIG. 8) of the second adhesive layer 462 corresponding to the second bending area BA2 may be formed by the curable adhesive, or both the second area 462b and the third area may be formed by the curable adhesive. Accordingly, a black dye or a black pigment may be included only in the third area 462c instead of the second area 462b of the second adhesive layer 462, and a black dye or a black pigment may be included in both the second area 462b and the third area 462c.

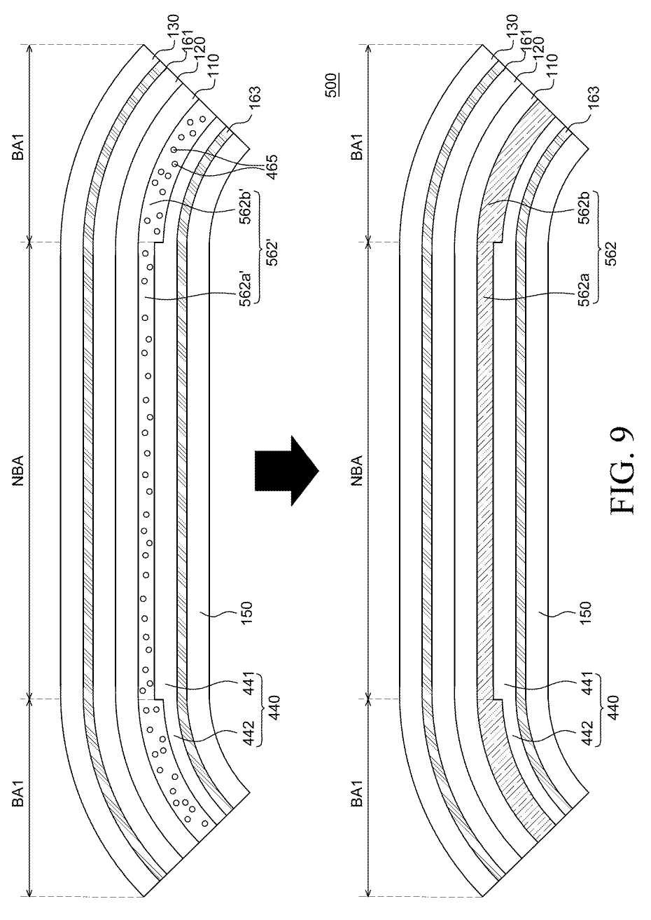

FIG. 9 is a schematic cross-sectional view of a display device according to still another exemplary embodiment of the present disclosure.

In FIG. 9, a schematic cross-section of the display device before and after the curing process of the second adhesive layer 562 is described. Referring to FIG. 9, an adhesive 562′ for forming a second adhesive layer is disposed between the display panel 110 and the back plate 440. Compared to the display device 400 illustrated in FIG. 8, in FIG. 9, the adhesive 562′ may include a pressure sensitive adhesive 562a′ disposed in an area corresponding to the non-bending area NBA and a curable adhesive 562b′ disposed in an area corresponding to the first bending area BA. both the pressure sensitive adhesive 562a′ and the curable adhesive 562b′ may all further include a black dye or a black pigment.

In particular, when both the pressure-sensitive adhesive 562a′ and the curable adhesive 562b′ include encapsulated discolored particles 465 or a discoloration resin material as a black dye, in the process of curing the curable adhesive 562b′ later, ultraviolet UV or heat is also irradiated to the pressure-sensitive adhesive 562a′ corresponding to the non-bending area NBA, such that all the second adhesive layer 462 may have a black color.

Although the case where the second area 562b of the second adhesive layer 562 corresponding to the first bending area BA1 is formed by the curable adhesive has been illustrated in FIG. 9, referring to FIGS. 3 and 4, only the third area (not shown in FIG. 9) of the second adhesive layer 562 corresponding to the second bending area BA2 may be formed by the curable adhesive, or both the second area 562b and the third area may be formed by the curable adhesive.

The exemplary embodiments of the present disclosure can also be described as follows:

According to an aspect of the present disclosure, there is provided a display device. The display device disclosure includes a display panel including a non-bending area, a first bending area corresponding to a side portion of the non-bending area, and a second bending area positioned between two first bending areas to correspond to a corner of the non-bending area; a back plate supporting the display panel at a lower portion of the display panel; and an adhesive layer disposed between the display panel and the back plate and including a first area corresponding to the non-bending area, a second area corresponding to the first bending area, and a third area corresponding to the second bending area, the first area and the third area having different physical properties from each other.

The first area and the third area may be formed of different materials.

The first area may be made of a pressure sensitive adhesive, and the third area may be made of an optical clear adhesive.

The Young’s modulus value of the first area may be smaller than the Young’s modulus value of the third area.

The third area may be made of a curable adhesive.

The second area may have a physical property different from that of the first area and may have the same physical property as that of the third area.

The second area may be formed of the same material as the third area.

The third area may include a black dye or a black pigment.

The back plate may include a first back plate corresponding to the first area, a second back plate corresponding to the second area, and a third back plate corresponding to the third area.

The thickness of the third back plate may be smaller than the thickness of the first back plate, and a step may be formed between the first back plate and the third back plate.

The thickness of the third back plate may decrease with increasing distance from the first back plate.

The third back plate may include a plurality of concave patterns formed on an upper surface.

The third back plate may include a plurality of uneven patterns formed on an upper surface.

The third back plate may include a plurality of holes, and the adhesive layer may extend inside the plurality of holes.

The second back plate may include a plurality of holes, and the third back plate may include a larger number of holes than the second back plate based on the same area.

The display device may further include a cover glass which is located on the top of the display panel and includes a front surface portion corresponding to the non-bending area, a first curved surface portion which corresponds to the first bending area and extends from the front surface portion to be bent with a specific radius of curvature, and a second curved surface portion which corresponds to the second bending area and is disposed between two first curved surface portions.

The third area may include discolored particles according to heat or energy irradiation.

The discolored particles may be encapsulated pigment particles having a structure surrounded by the capsule film.

The first area may further include discolored particles.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present invention. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a non-bending area, a first bending area corresponding to a side portion of the non-bending area, and a second bending area positioned between two first bending areas so as to correspond to a corner of the non-bending area;
a back plate supporting the display panel at a lower portion of the display panel; and
an adhesive layer disposed between the display panel and the back plate and including a first area corresponding to the non-bending area, a second area corresponding to the first bending area, and a third area corresponding to the second bending area,
wherein the first area and the third area have different physical properties.

2. The display device according to claim 1, wherein the first area and the third area are formed of different materials.

3. The display device according to claim 2, wherein the first area is formed of a pressure sensitive adhesive and the third area is formed of an optically clear adhesive.

4. The display device according to claim 2, wherein a Young’s modulus value of the first area is smaller than a Young’s modulus value of the third area.

5. The display device according to claim 4, wherein the third area is formed of a curable adhesive.

6. The display device according to claim 1, wherein the second area has different physical properties from the first area and has the same physical properties as the third area.

7. The display device according to claim 6, wherein the second area is formed of the same material as the third area.

8. The display device according to claim 1, wherein the third area includes a black dye or a black pigment.

9. The display device according to claim 1, wherein the back plate includes a first back plate corresponding to the first area, a second back plate corresponding to the second area, and a third back plate corresponding to the third area.

10. The display device according to claim 9, wherein a thickness of the third back plate is smaller than a thickness of the first back plate, and
wherein a step is formed between the first back plate and the third back plate.

11. The display device according to claim 9, wherein the thickness of the third back plate decreases with increasing distance from the first back plate.

12. The display device according to claim 9, wherein the third back plate includes a plurality of concave patterns formed on an upper surface thereof.

13. The display device according to claim 9, wherein the third back plate includes a plurality of uneven patterns formed on an upper surface thereof.

14. The display device according to claim 9, wherein the third back plate includes a plurality of holes, and
wherein the adhesive layer extends inside the plurality of holes.

15. The display device according to claim 10, wherein the second back plate includes a plurality of holes, and
wherein the third back plate includes a larger number of holes than the second back plate based on the same area.

16. The display device according to claim 1, further comprising:
a cover glass which is located on the top of the display panel and includes a front surface portion corresponding to the non-bending area, a first curved surface portion which corresponds to the first bending area and extends from the front surface portion to be bent with a specific radius of curvature, and a second curved surface portion which corresponds to the second bending area and is disposed between two first curved surface portions.

17. The display device according to claim 1, wherein the third area includes color-changing particles that change color in response to heat or energy irradiation.

18. The display device according to claim 17, wherein the color-changing particles comprise encapsulated pigment particles having a structure surrounded by a capsule film.

19. The display device according to claim 17, wherein the first area further includes the color-changing particles.

20. The display device according to claim 1, wherein the first area and the third area have different physical properties including at least one of adhesive strength or elastic modulus.
